(19) United States
(12) Patent Application Publication
(10) Pub. No.: US 2023/0231050 A1
(43) Pub. Date: Jul. 20, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventors: Yutong SHEN, Hefei City (CN); Jifeng TANG, Hefei City (CN)

(21) Appl. No.: 17/661,340

(22) Filed: Apr. 29, 2022

Related U.S. Application Data
(63) Continuation of application No. PCT/CN2022/078651, filed on Mar. 1, 2022.

(30) Foreign Application Priority Data
Jan. 17, 2022 (CN) 202210047626.2

(51) Int. Cl. H01L 29/78; H01L 29/161; H01L 29/08; H01L 29/45; H01L 21/02; H01L 21/285

(52) U.S. Cl. CPC H01L 29/7848; H01L 21/0257; H01L 21/02532; H01L 21/28518; H01L 29/45; H01L 29/161; H01L 29/0847

(57) ABSTRACT

The present disclosure provides a semiconductor structure and a manufacturing method thereof, and relates to the technical field of semiconductors. The semiconductor structure includes: a base, including a doped region; a recess, located in the doped region; and a gradient layer, filling the recess, wherein a doping concentration of the gradient layer varies gradually from a bottom of the recess upwards.

### CROSS-REFERENCE TO RELATED APPLICATIONS

This is a continuation of International Application No. PCT/CN2022/078651, filed on Mar. 1, 2022, which claims the priority to Chinese Patent Application No. 202210047626.2, titled “SEMICONDUCTOR STRUCTURE AND MANUFACTURING METHOD THEREOF” and filed on Jan. 17, 2022. The entire contents of International Application No. PCT/CN2022/078651 and Chinese Patent Application No. 202210047626.2 are incorporated herein by reference.

### TECHNICAL FIELD

The present disclosure relates to, but is not limited to, a semiconductor structure and a manufacturing method thereof.

### BACKGROUND

During manufacturing of a semiconductor structure, a doped structure may be embedded in a base of the semiconductor structure to improve carrier mobility, so as to improve device performance of the semiconductor structure.

In the foregoing semiconductor structure, there may be a problem of lattice mismatch between the doped structure and the original base. This not only cause uneven growth morphology, but also cause electric leakage and affect device stability.

### SUMMARY

An overview of the subject matter detailed in the present disclosure is provided below, which is not intended to limit the protection scope of the claims.

The present disclosure provides a semiconductor structure and a manufacturing method thereof.

A first aspect of the present disclosure provides a semiconductor structure, including:
a base, including a doped region;
a recess, located in the doped region; and
a gradient layer, filling the recess, wherein a doping concentration of the gradient layer varies gradually from a bottom of the recess upwards.

A second aspect of the present disclosure provides a transistor, including the semiconductor structure described above, wherein the semiconductor structures are located in a source region and a drain region of the transistor.

A third aspect of the present disclosure provides a method of manufacturing a semiconductor structure, including:
providing a base, wherein the base includes a doped region;
forming a recess in the doped region of the base; and
forming a gradient layer, wherein the gradient layer fills the recess, and a doping concentration of the gradient layer varies gradually from a bottom of the recess upwards.

Other aspects of the present disclosure are understandable upon reading and understanding of the accompanying drawings and detailed description.

### BRIEF DESCRIPTION OF THE DRAWINGS

The accompanying drawings incorporated into the specification and constituting part of the specification illustrate the embodiments of the present disclosure, and are used together with the description to explain the principles of the embodiments of the present disclosure. In these accompanying drawings, similar reference numerals are used to represent similar elements. The accompanying drawings in the following description are part rather than all of the embodiments of the present disclosure. Those skilled in the art may derive other accompanying drawings based on these accompanying drawings without creative efforts.

FIG. 1 is a schematic structural diagram of a semiconductor structure in the related art;

FIG. 2 is a schematic structural diagram of a semiconductor structure according to an exemplary embodiment;

FIG. 3 is a schematic structural diagram of a semiconductor structure according to an exemplary embodiment;

FIG. 4 is a schematic structural diagram of a semiconductor structure according to an exemplary embodiment;

FIG. 5 is a flowchart of a method of manufacturing a semiconductor structure according to an exemplary embodiment;

FIG. 6 is a flowchart of a method of manufacturing a semiconductor structure according to an exemplary embodiment;

FIG. 7 is a flowchart of a method of manufacturing a semiconductor structure according to an exemplary embodiment;

FIG. 8 is a schematic diagram of a base provided in a method of manufacturing a semiconductor structure according to an exemplary embodiment;

FIG. 9 is a schematic diagram of forming a recess in a method of manufacturing a semiconductor structure according to an exemplary embodiment;

FIG. 10 is a schematic diagram of forming a heavily doped region in a method of manufacturing a semiconductor structure according to an exemplary embodiment;

FIG. 11 is a schematic diagram of forming a first structure layer in a method of manufacturing a semiconductor structure according to an exemplary embodiment;

FIG. 12 is a schematic diagram of forming multiple structure layers in a method of manufacturing a semiconductor structure according to an exemplary embodiment;

FIG. 13 is a schematic diagram of forming a protective layer in a method of manufacturing a semiconductor structure according to an exemplary embodiment;

FIG. 14 is a schematic diagram of forming a through hole in a method of manufacturing a semiconductor structure according to an exemplary embodiment; and

FIG. 15 is a schematic diagram of forming a conductive layer in a method of manufacturing a semiconductor structure according to an exemplary embodiment.

### REFERENCE NUMERALS

100. base; 110. heavily doped region; 120. lightly doped region; 130. Halo region; 200. recess; 300. gradient layer; 310. structure layer; 311. first structure layer; 312. second structure layer; 313. third structure layer; 320. protective layer; 321. through hole; 400. conductive layer; 500. metal layer;
10. base; 11. semiconductor substrate; 12. well region; 20. gate oxide layer; 30. gate; 40. dielectric layer sidewall;
10′. base; 20′. gate oxide layer; 30′. gate; 40′. doped structure.

### DETAILED DESCRIPTION

The technical solutions in the embodiments of the present disclosure are described below clearly and completely with reference to the accompanying drawings in the embodiments of the present disclosure. Apparently, the described embodiments are merely some rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

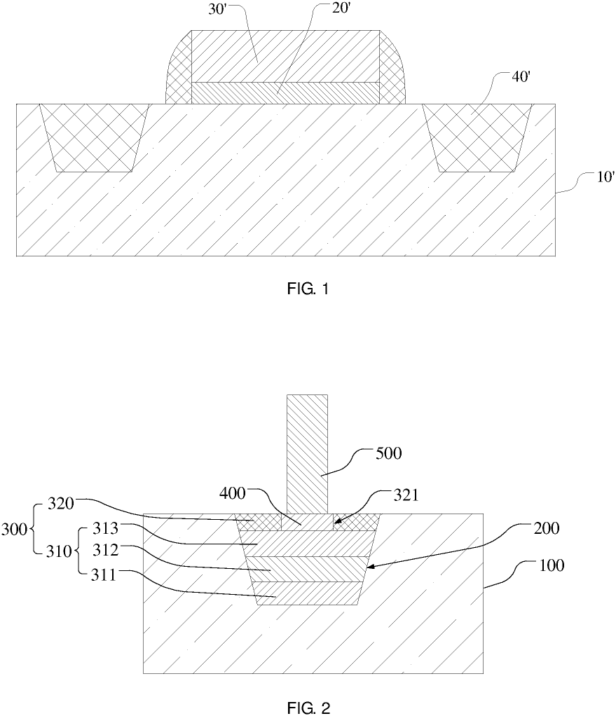

In an existing semiconductor structure, a doped structure is embedded in a base to improve carrier mobility. For example, as shown in FIG. 1, the semiconductor structure is a transistor structure. The transistor structure includes a base 10′. The base 10′ has an active region, a drain region, and a channel region. A gate oxide layer 20′ is formed in the channel region. A gate 30′ is formed on the gate oxide layer 20′. A doped structure 40′ is embedded in the source region and the drain region. The doped structure 40′ is, for example, a silicon-germanium structure. It is found by the applicant that, because a material of the base 10′ is usually silicon, and there is a problem of lattice mismatch between silicon and the silicon-germanium structure, uneven growth morphology is caused, and electric leakage is also caused and stability of the transistor structure is affected.

Based on this, an exemplary embodiment of the present disclosure provides a semiconductor structure. As shown in FIG. 2, the semiconductor structure includes: a base 100, a recess 200 provided in the base 100, and a gradient layer 300 that fills the recess 200. The base 100 is made of, for example, silicon. The base 100 includes a doped region. The doped region is used, for example, for forming a source/drain region of a transistor. The recess 200 is provided in the doped region. The gradient layer fills the recess 200, and a doping concentration of the gradient layer 300 varies gradually from the bottom of the recess 200 upwards. The doping concentration herein refers to a proportion of a dopant to a total material. For example, when the gradient layer 300 is a silicon-germanium structure, the doping concentration is germanium content in the silicon-germanium structure. The gradual change herein may be gradually becoming smaller, or gradually becoming larger, or first becoming smaller and then becoming larger, or first becoming larger and then becoming smaller. This is not limited in this embodiment.

In the semiconductor structure of this embodiment, the recess 200 is provided in the doped region of the base 100, and the recess 200 is filled with the gradient layer 300, where the doping concentration of the gradient layer 300 varies gradually from the bottom of the recess 200 upwards. The gradient layer 300 with the gradually varying doping concentration can better match a recess wall of the recess 200. In this way, electric leakage problems caused by lattice mismatch between the recess wall of the recess 200 and the gradient layer 300 can be reduced while carrier mobility is improved.

In some embodiments, the gradient layer 300 is of an integral structure. In the integral structure, the doping concentration varies gradually along a direction from the bottom of the recess 200 upwards. In some other embodiments, the gradient layer 300 is of a multilayer structure. Different doping concentrations are set for different structure layers in the multilayer structure, such that the doping concentration of the gradient layer 300 varies gradually from the bottom of the recess 200 upwards.

According to an exemplary embodiment, as shown in FIG. 2, the gradient layer 300 includes multiple structure layers 310 stacked in sequence, and doping concentrations of adjacent structure layers 310 are different, that is, for each of the structure layers 310, the doping concentration is the same, but doping concentrations of adjacent structure layers 310 are different, such that a desired doping concentration variation can be achieved. A layer quantity of the structure layers 310 is not limited, and can be set according to specific requirements. For example, in the embodiment shown in FIG. 2, from the bottom of the recess 200 upwards, the multiple structure layers 310 sequentially include a first structure layer 311, a second structure layer 312, and a third structure layer 313. The first structure layer 311 and the second structure layer 312 have different doping concentrations. The second structure layer 312 and the third structure layer 313 have different doping concentrations. The first structure layer 311 and the third structure layer 313 may have the same doping concentration or may have different doping concentrations. In an embodiment in which the doping concentration of the gradient layer 300 increases gradually from the bottom of the recess 200 upwards, doping concentrations of the multiple structure layers 310 increase gradually from the bottom of the recess 200 upwards. For example, in the embodiment shown in FIG. 2, a doping concentration of the third structure layer 313 is larger than a doping concentration of the second structure layer 312, and the doping concentration of the second structure layer 312 is larger than a doping concentration of the first structure layer 311. In an embodiment in which the doping concentration of the gradient layer 300 decreases gradually from the bottom of the recess 200 upwards, a doping concentration of the first structure layer 311 is larger than a doping concentration of the second structure layer 312, and the doping concentration of the second structure layer 312 is larger than a doping concentration of the third structure layer 313. In an embodiment in which the doping concentration of the gradient layer 300 first becomes larger and then smaller, a doping concentration of the second structure layer 312 is larger than a doping concentration of the first structure layer 311 and is larger than a doping concentration of the third structure layer 313. In an embodiment in which the doping concentration of the gradient layer 300 first becomes smaller and then larger, a doping concentration of the second structure layer 312 is smaller than a doping concentration of the first structure layer 311 and is smaller than a doping concentration of the third structure layer 313.

The gradient layer 300 further includes a protective layer 320 provided on the multiple structure layers 310. The protective layer 320 can well protect the multiple structure layers 310. In this embodiment, doping concentrations of the multiple structure layers 310 first increase and then decrease from the bottom of the recess 200 upwards, that is, among the multiple structure layers 310, a structure layer 310 close to the protective layer 320 has a relatively small doping concentration to well match the protective layer 320, a structure layer 310 close to the base 100 has a relatively small doping concentration to well match the base 100, and a structure layer 310 away from the protective layer 320 and the base 100 has a relatively large doping concentration, so as to improve carrier mobility of the gradient layer 300. The doping concentrations of the multiple structure layers 310 first increase and then decrease from the bottom of the recess 200 upwards, such that device performance of the semiconductor structure can be ensured, electric leakage caused by lattice mismatch can be avoided, and conductivity performance of the gradient layer 300 can be improved.

In an embodiment, a thickness of each of the structure layers 310 is 2 nm to 10 nm, thereby ensuring reliability of a formation process of each of the structure layers 310, and ensuring that a layer quantity of the structure layers 310 in the gradient layer 300 is controllable.

According to an exemplary embodiment, the multiple structure layers 310 are multiple silicon-germanium layers, that is, each of the structure layers 310 is a structure layer 310 obtained by doping a germanium material in silicon, and the protective layer 320 is a silicon layer. Germanium content in the multiple structure layers 310 first increases and then decreases from the bottom of the recess 200 upwards, that is, among the multiple structure layers 310, a structure layer 310 located on an upper side has relatively small germanium content, a structure layer 310 located on a lower side has relatively small germanium content, and a structure layer 310 located in the middle has relatively large germanium content. In an example, the multiple structure layers 310 sequentially include a first structure layer 311, a second structure layer 312, and a third structure layer 313. Germanium content in the second structure layer 312 is larger than germanium content in the first structure layer 311 and is larger than germanium content in the third structure layer 313.

In this embodiment, the structure layer 310 is a silicon-germanium layer, and the protective layer 320 is a silicon layer. The structure layer 310 located on the upper side has relatively small germanium content, such that the silicon layer (the protective layer 320) above can be well matched. The structure layer 310 located on the lower side also has relatively small germanium content, such that the silicon layer (the base 100) located on the lower side can be well matched. The structure layer 310 located in the middle has relatively large germanium content. Because the structure layer 310 in the middle is not in contact with the silicon layers (the protective layer 320 and the base 100), the structure layer 310 in the middle can be doped with more germanium content, so as to improve carrier mobility thereof and improve conductivity performance thereof.

In an embodiment, among the multiple silicon-germanium layers, a germanium content of a silicon-germanium layer close to the bottom of the recess 200 is 25 wt% to 30 wt%, a germanium content of a silicon-germanium layer with the largest germanium content is 35 wt% to 40 wt%, and a germanium content of a silicon-germanium layer close to the top of the recess 200 is 25 wt% to 30 wt%. A germanium content difference between adjacent silicon-germanium layers is 1 wt% to 5 wt%. This not only can ensure that mismatch between silicon-germanium layers is not caused due to an extremely large germanium content difference between the silicon-germanium layers, but also can prevent the germanium content in the silicon-germanium layer in the middle from being affected by an extremely small germanium content difference between the silicon-germanium layers, thereby ensuing both reliability and conductivity performance of the semiconductor structure.

According to an exemplary embodiment, as shown in FIG. 2, the semiconductor structure further includes a conductive layer 400 and a metal layer 500. The protective layer 320 includes a through hole 321. The conductive layer 400 fills the through hole 321. The metal layer 500 is provided on the conductive layer 400 and electrically connected to the conductive layer 400. The metal layer 500 and the conductive layer 400 are provided and are in contact with the structure layer 310 through the through hole 321, such that the structure layer 310 is electrically connected to each of the other layer structures. A material of the conductive layer 400 is a metal compound. For example, the material of the conductive layer 400 is cobalt silicide or nickel silicide. The conductivity between the metal layer 500 and the structure layer 310 is achieved by metal silicide, such that a contact resistance can be reduced, thereby improving device performance of the semiconductor structure. The metal layer 500 may be made of tungsten, copper, gold, silver, or other materials.

In this embodiment, the provision of the protective layer 320 can also help the formation of the metal compound, that is, the conductive layer 400. In an example, the through hole 321 of the protective layer 320 may be filled with a metallic material such as cobalt or nickel. Subsequently, the metallic material in the through hole 321 reacts with a material of the protective layer 320 through high temperature annealing, thereby generating the metal compound for reducing the contact resistance.

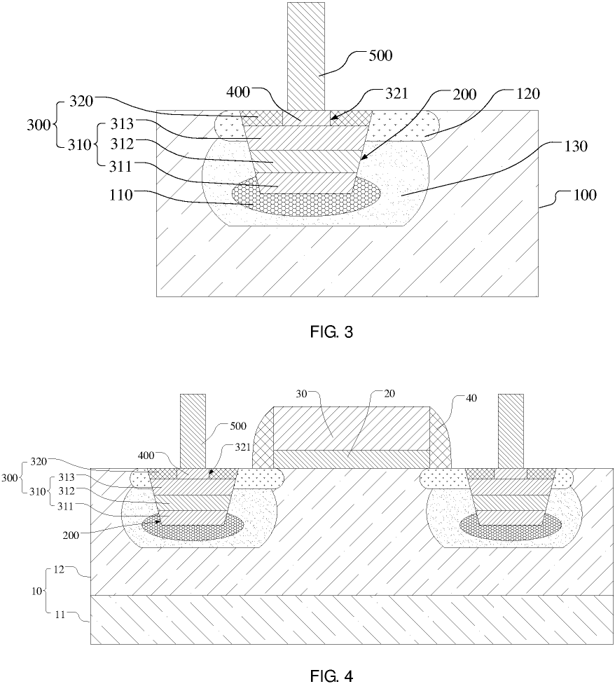

According to an exemplary embodiment, as shown in FIG. 3, the doped region includes a heavily doped region 110 and a lightly doped region 120. The heavily doped region 110 and the lightly doped region 120 are both located around the recess, and the heavily doped region 110 is closer to the bottom of the recess 200. The lightly doped region 120 is a structure used by a MOSFET to attenuate an electric field in the drain region, to improve a hot carrier injection effect, that is, a lightly doped region is set close to the source region and the drain region, to allow the region to withstand partial voltage, thereby effectively preventing a hot carrier injection effect. The heavily doped region 110 is closer to the bottom of the recess 200. For example, the bottom of the recess 200 is higher than the lowest point of the heavily doped region 110, such that a bottom wall of the recess 200 and a sidewall region close to the bottom wall form the heavily doped region 110. In addition, vacancies or defects are caused in the heavily doped region 110 formed through doping by using heavy ions, such that stress of the lattice mismatch can be released, allowing the recess wall of the recess 200 to better match the gradient layer 300. Still referring to FIG. 3, a heavily doped Halo region 130 is further provided below the lightly doped region 120, to reduce a short-channel effect of the device and suppress a threshold voltage drop.

According to an exemplary embodiment of the present disclosure, this embodiment provides a transistor. As shown in FIG. 4, a structure of the transistor includes: a base 10, a channel provided in the base 10, and a gate oxide layer 20 and a gate 30 located above the channel. A dielectric layer sidewall 40 is provided on each of two sides of the gate oxide layer 20 and the gate 30. The foregoing semiconductor structures are provided in a source region and a drain region of the base 10, that is, the source region and the drain region are each provided with a recess 200, and the recess 200 is filled with a gradient layer 300. A doping concentration of the gradient layer 300 varies gradually from the bottom of the recess 200 upwards. The gradient layer 300 is provided in the source region and the drain region, such that the gradient layer 300 with the gradually varying doping concentration can better match a recess wall of the recess 200. In this way, electric leakage problems caused by lattice mismatch between the recess wall of the recess 200 and the gradient layer 300 can be reduced while carrier mobility is improved, thereby improving device performance of the transistor.

For example, as shown in FIG. 4, the base 10 includes a semiconductor substrate 11 and a well region 12 with a first conductive type on the semiconductor substrate 11, such as an N-type well region or a P-type well region. In this embodiment, the lightly doped region 120 is formed by doping ions of the first conductive type, and the Halo region 130 is formed by doping ions of a second conductive type, that is, the first conductive type is opposite to the second conductive type. If the ions of the first conductive type are N-type ions, the ions of the second conductive type are P-type ions. If the ions of the first conductive type are P-type ions, the ions of the second conductive type are N-type ions.

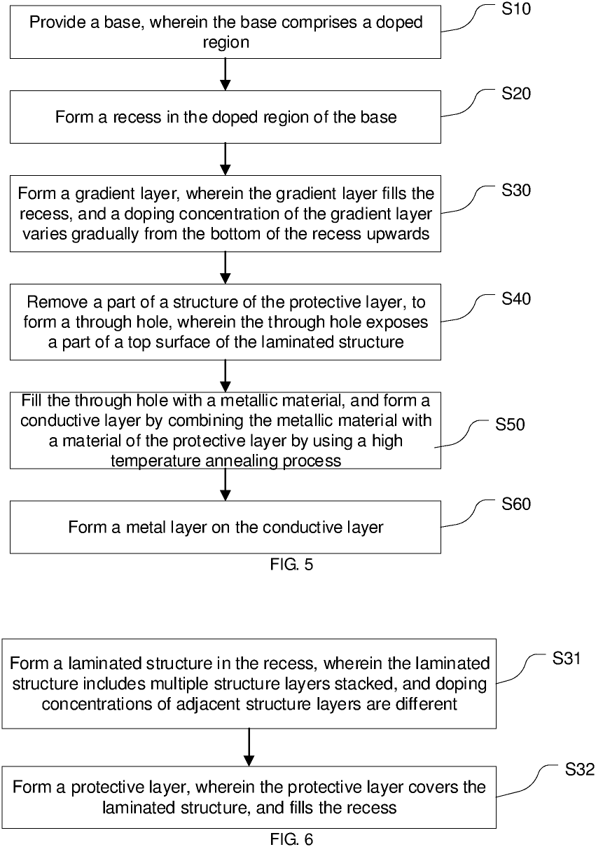

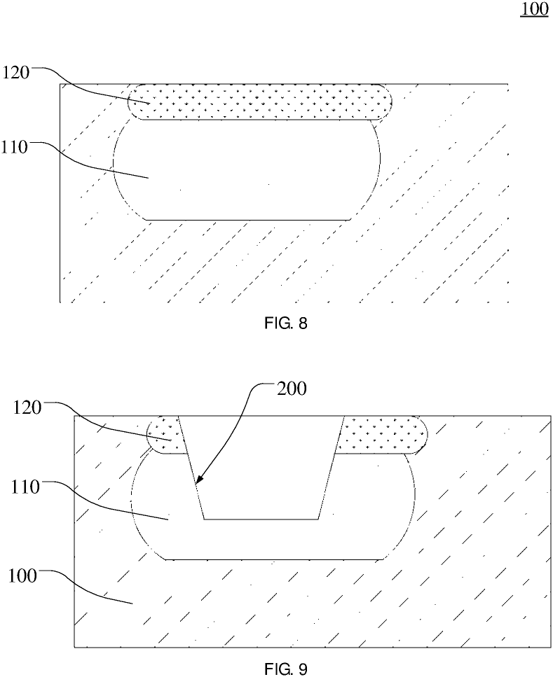

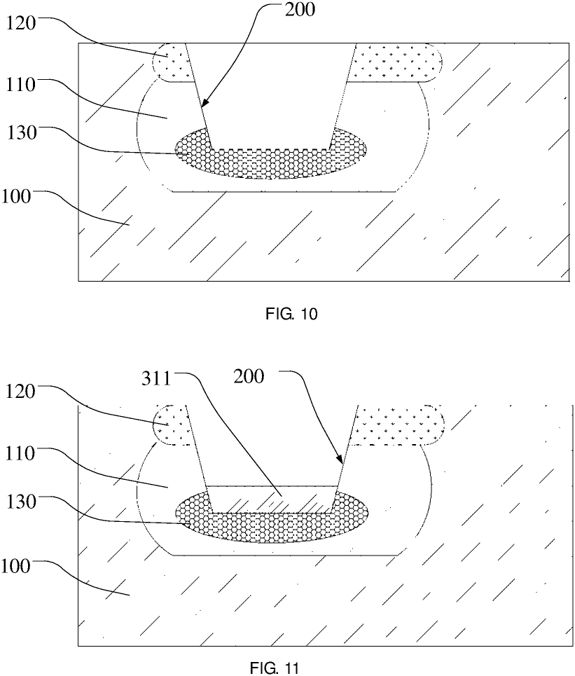

An exemplary embodiment of the present disclosure provides a method of manufacturing a semiconductor structure. FIG. 5 is a flowchart of a method of manufacturing a semiconductor structure according to an exemplary embodiment of the present disclosure. FIG. 8 to FIG. 15 are schematic diagrams of various stages of a method of manufacturing a semiconductor structure. The method of manufacturing a semiconductor structure is described below with reference to FIG. 8 to FIG. 15.

As shown in FIG. 5, an exemplary embodiment of the present disclosure provides a method of manufacturing a semiconductor structure, including the following steps:

Step S10: Provide a base, where the base comprises a doped region.

For example, as shown in FIG. 8, the base 100 serves as a support component and is used to support other components provided thereon. The base 100 may be made of a semiconductor material. The semiconductor material may be one or more of silicon, germanium, silicon-germanium compounds, and silicon-carbon compounds.

According to an exemplary embodiment, as shown in FIG. 8, a lightly doped region 120 is formed by doping a first region located in a surface layer of the base 100. In an example, the first region is doped by using ions of a first conductive type to form the lightly doped region 120. A heavily doped region 110 is located below the lightly doped region 120. A recess 200 is formed at least partially in the heavily doped region 110 and the lightly doped region 120, and the bottom of the recess 200 is higher than the lowest point of the heavily doped region 110. The lightly doped region 120 is a structure used by a MOSFET to attenuate an electric field in a drain region, to improve a hot carrier injection effect, that is, a lightly doped region is set close to a source region and the drain region, to allow the region to withstand partial voltage, thereby effectively preventing the hot carrier injection effect.

Further, a heavily doped Halo region 130 may further be provided below the lightly doped region 120. In an example, ions of a second conductive type are used for doping to form the Halo region 130. That is, the first conductive type is opposite to the second conductive type. If the ions of the first conductive type are N-type ions, the ions of the second conductive type are P-type ions. If the ions of the first conductive type are P-type ions, the ions of the second conductive type are N-type ions. The provision of the Halo region 130 can reduce a short-channel effect of a device and suppress a threshold voltage drop.

Step S20: Form a recess in the doped region of the base.

In this step, the recess 200 may be formed in the doped region of the base 100 through photolithography, etching, or in other manners. As shown in FIG. 9, the recess 200 is formed at least partially in the heavily doped region 110 and the lightly doped region 120, and the bottom of the recess 200 is higher than the lowest point of the heavily doped region 110.

Step S30: Form a gradient layer, where the gradient layer fills the recess, and a doping concentration of the gradient layer varies gradually from the bottom of the recess upwards.

In this step, a gradient layer 300 may be formed by depositing a doped semiconductor material, or a semiconductor material layer is formed by depositing an undoped semiconductor material to fill the recess 200, and then doped impurities are implanted into the semiconductor material layer through a thermal diffusion process or an ion implantation process to form the gradient layer 300.

In the semiconductor structure formed in this embodiment, the recess 200 is formed in the doped region of the base 100, and the gradient layer 300 is formed in the recess 200, where the doping concentration of the gradient layer 300 varies gradually from the bottom of the recess 200 upwards. The gradient layer 300 with the gradually varying doping concentration can better match a recess wall of the recess 200. In this way, electric leakage problems caused by lattice mismatch between the recess wall of the recess 200 and the gradient layer 300 can be reduced while carrier mobility is improved.

According to an exemplary embodiment of the present disclosure, this embodiment is a further description of step S30 in the foregoing embodiment.

As shown in FIG. 6, the forming a gradient layer includes the following steps:

S31. Form a laminated structure in the recess, where the laminated structure includes multiple structure layers stacked, and doping concentrations of adjacent structure layers are different.

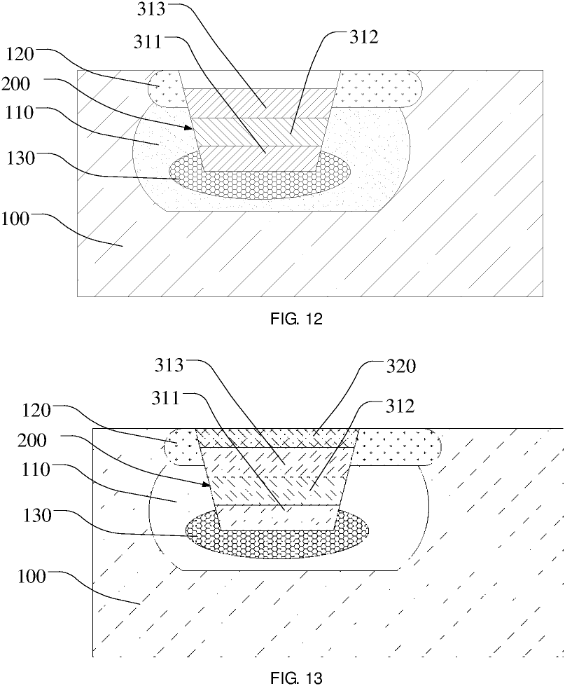

In this step, as shown in FIG. 12, different doping concentrations are set for different structure layers 310 in the multiple structure layers 310, such that the doping concentration of the gradient layer 300 varies gradually from the bottom of the recess 200 upwards. That doping concentrations of adjacent structure layers 310 are different means that for each of the structure layers 310, the doping concentration is the same, but doping concentrations of adjacent structure layers 310 are different, such that a desired doping concentration variation can be achieved. A layer quantity of the structure layers 310 is not limited, and can be set according to specific requirements. For example, in the embodiment shown in FIG. 12, from the bottom of the recess 200 upwards, the multiple structure layers 310 sequentially include a first structure layer 311, a second structure layer 312, and a third structure layer 313. The first structure layer 311 and the second structure layer 312 have different doping concentrations. The second structure layer 312 and the third structure layer 313 have different doping concentrations. The first structure layer 311 and the third structure layer 313 may have the same doping concentration or may have different doping concentrations.

In an example, a semiconductor material layer may be formed through deposition by using an atomic layer deposition (ALD) process, a chemical vapor deposition (CVD) process, or other processes, and the semiconductor material layer is doped to form the structure layer 310. In another embodiment, in step S31, multiple rounds of epitaxial growth are performed in the recess 200, and each round of epitaxial growth forms one of the structure layers 310. A required doping concentration is achieved by controlling material content during the epitaxial growth. The use of epitaxial growth to form the structure layers 310 can control a doping concentration of each of the structure layers 310 more accurately, thereby improving process controllability.

S32. Form a protective layer, where the protective layer covers the laminated structure, and fills the recess.

In this example, as shown in FIG. 13, a protective layer 320 may be formed through deposition by using an ALD process, a CVD process, or other processes, or the protective layer 320 may be formed through epitaxial growth. The laminated structure is well protected by forming the protective layer 320 on the laminated structure, and the protective layer 320 is used to fill the recess 200 to ensure flatness.

In this embodiment, doping concentrations of the multiple structure layers 310 first increase and then decrease from the bottom of the recess 200 upwards, that is, among the multiple structure layers 310, a structure layer 310 close to the protective layer 320 has a relatively small doping concentration to well match the protective layer 320, a structure layer 310 close to the base 100 has a relatively small doping concentration to well match the base 100, and a structure layer 310 away from the protective layer 320 and the base 100 has a relatively large doping concentration, so as to improve carrier mobility of the gradient layer 300. The doping concentrations of the multiple structure layers 310 first increase and then decrease from the bottom of the recess 200 upwards, such that device performance of the formed semiconductor structure can be ensured, electric leakage caused by lattice mismatch can be avoided, and conductivity performance of the gradient layer 300 can be improved.

According to an exemplary embodiment, the structure layer 310 is a silicon-germanium layer, and the protective layer 320 is a silicon layer. In this way, the structure layer 310 located on the upper side has relatively small germanium content, such that the silicon layer (the protective layer 320) above can be well matched. The structure layer 310 located on the lower side also has relatively small germanium content, such that the silicon layer (the base 100) located on the lower side can be well matched. The structure layer 310 located in the middle has relatively large germanium content. Because the structure layer 310 in the middle is not in contact with the silicon layers (the protective layer 320 and the base 100), the structure layer 310 in the middle can be doped with more germanium content, so as to improve carrier mobility thereof and improve conductivity performance thereof.

In this embodiment, step S31 includes:

S311. Under the condition of 400° C. to 1000° C., perform selective epitaxy of silicon-germanium in the recess, and control germanium content in silicon-germanium to obtain a first structure layer with a required doping concentration, referring to FIG. 11.

S312. Continue to perform multiple rounds of selective epitaxy on the first structure layer, and control a thickness of each round of silicon-germanium growth in a range of 2-10 nm, to form multiple structure layers.

In an example, as shown in FIG. 12, selective epitaxy is performed on a first structure layer 311 to form a second structure layer 312, and selective epitaxy is performed on the second structure layer 312 to form a third structure layer 313. A doping concentration of the second structure layer 312 is larger than a doping concentration of the first structure layer 311 and is larger than a doping concentration of the third structure layer 313.

In this embodiment, a germanium content of a silicon-germanium layer close to the bottom of the recess 200 is 25 wt% to 30 wt%, a germanium content of a silicon-germanium layer with the largest germanium content is 35 wt% to 40 wt%, and a germanium content of a silicon-germanium layer close to the top of the recess 200 is 25 wt% to 30 wt%. A germanium content difference between adjacent silicon-germanium layers is 1 wt% to 5 wt%. This not only can ensure that mismatch between silicon-germanium layers is not caused due to an extremely large germanium content difference between the silicon-germanium layers, but also can prevent the germanium content in the silicon-germanium layer in the middle from being affected by an extremely small germanium content difference between the silicon-germanium layers, thereby ensuing both reliability and conductivity performance of the semiconductor structure.

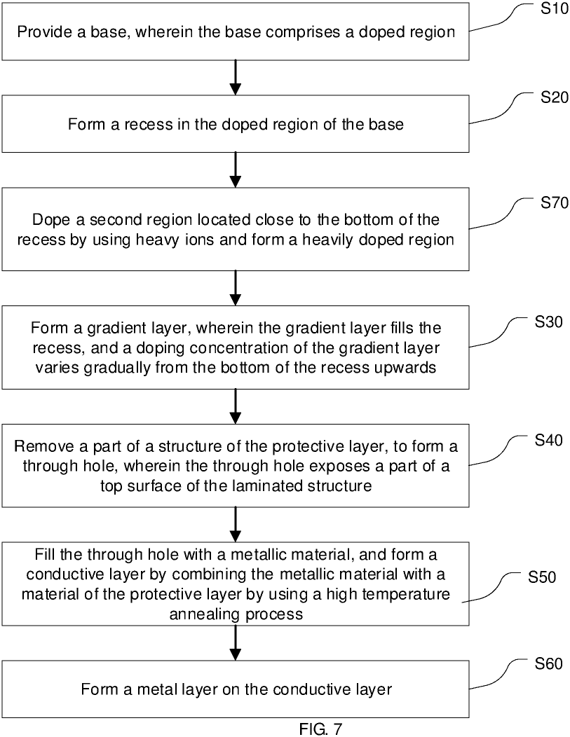

According to an exemplary embodiment, as shown in FIG. 7, after the forming a gradient layer, the following step is further performed:

S40: Remove a part of a structure of the protective layer, to form a through hole, where the through hole exposes a part of a top surface of the laminated structure.

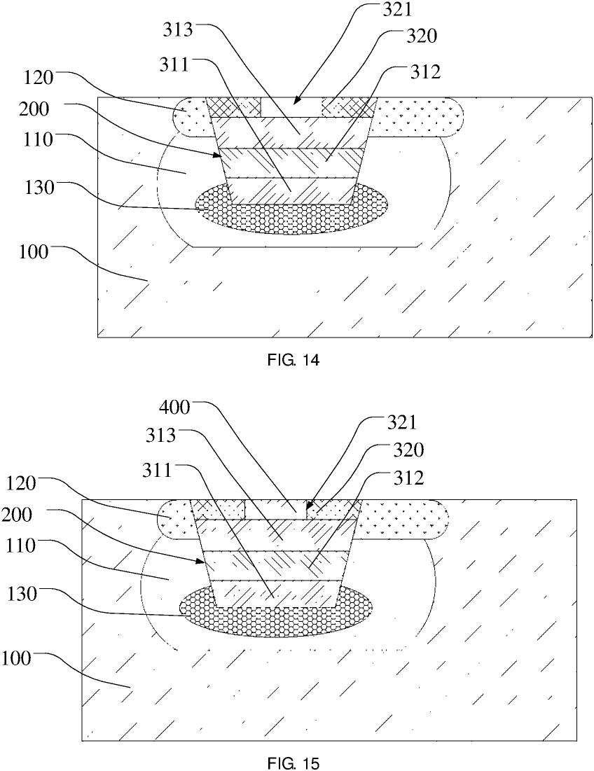

In this step, as shown in FIG. 14, a through hole 321 may be formed in the protective layer 320 through photolithography, etching, or in other manners. In an example, a bottom anti-reflective coating (BARC) layer is formed on an upper surface of the protective layer 320, a patterned photoresist layer is formed on the BARC layer, and patterns in the patterned photoresist layer are transferred to the protective layer 320 through dry etching, to form the through hole 321 in the protective layer 320.

S50: Fill the through hole with a metallic material, and form a conductive layer by combining the metallic material with a material of the protective layer by using a high temperature annealing process.

In this embodiment, as shown in FIG. 15, the through hole 321 is filled with a metallic material, and the metallic material in the through hole is combined with the protective layer 320 by using a high temperature annealing process to form a metal compound. Conductivity between the structure layer 310 and a metal layer 500 that is formed by using a subsequent process is achieved by using the metal compound, such that a contact resistance can be reduced, thereby improving device performance of the semiconductor structure. The metallic material is, for example, cobalt or nickel, which can be combined with silicon in the protective layer 320 to form cobalt silicide or nickel silicide.

S60: Form a metal layer on the conductive layer.

In this step, a material of the metal layer 500 is, for example, tungsten, copper, gold, or silver. The metal layer 500 may be formed through deposition by using an ALD process, a CVD process, or other processes.

According to an exemplary embodiment, before the forming a gradient layer 300, as shown in FIG. 6, the following step is further performed:

S70: Dope a second region located close to the bottom of the recess by using heavy ions and form a heavily doped region.

In this step, as shown in FIG. 9, before the gradient layer 300 is formed, heavy ion doping is performed in a region close to the bottom of the recess 200 to form the heavily doped region 110, and the heavily doped region 110 constitutes a bottom wall of the recess 200 and part of a sidewall close to the bottom. In addition, vacancies or defects are caused in the heavily doped region 110 formed through heavy ion doping, such that stress of lattice mismatch can be released, allowing the recess wall of the recess 200 to better match the gradient layer 300. Heavy ions used for the heavy ion doping include at least one of germanium, carbon, or helium.

In an embodiment, the heavily doped region 110 is in contact with the first structure layer 311. For example, a bottom surface of the first structure layer 311 is in contact with the bottom of the heavily doped region 110, and a side face of the first structure layer 311 is in contact with a side face of the heavily doped region 110, thereby releasing stress caused by lattice mismatch during the formation of the first structure layer 311.

According to an exemplary embodiment of the present disclosure, after the heavily doped region 110 is formed and before the gradient layer 300 is formed, the following step is further performed:

S80: Dope a third region close to a sidewall of the recess by using heavy ions to form a stress release region.

In this step, the heavy ions are used to dope the third region, such that vacancies or defects are caused in the sidewall of the recess 200, and stress caused by lattice mismatch during the formation of each structure layer 310 can be released during the formation of a subsequent structure layer 310, allowing the recess wall of the recess 200 to better match the gradient layer 300. The heavy ions for forming the heavily doped region 110 may be the same as or different from heavy ions for forming the stress release region. For example, the heavy ions used for the heavy ion doping include at least one of germanium, carbon, or helium.

The stress release region may be of an integral cylindrical structure, so as to enclose each structure layer above the first structure layer 311 in the gradient layer 300 as a whole. For example, in the embodiment shown in FIG. 3, the stress release region encloses the second structure layer 312 and the third structure layer 313. In another embodiment, there may alternatively be multiple stress release regions arranged from the bottom of the recess 200 upwards, and each stress release region corresponds to one structure layer 310, that is, each stress release region is in contact with a sidewall of one structure layer 310.

A doping concentration of the stress release region may be the same as a doping concentration of the heavily doped region 110, or may be different from the doping concentration of the heavily doped region 110. In some embodiments, the doping concentration of the heavily doped region 110 matches a doping concentration of the structure layer 310 in contact with the heavily doped region 110, and the doping concentration of the stress release region matches a doping concentration of the structure layer 310 in contact with the stress release region. For example, a stress release region corresponding to a structure layer with a relatively high doping concentration has a correspondingly high doping concentration. A stress release region corresponding to a structure layer with a relatively low doping concentration has a correspondingly low doping concentration.

For example, the multiple structure layers 310 of the gradient layer 300 include a first structure layer 311, a second structure layer 312, and a third structure layer 313 stacked in sequence. A doping concentration of the second structure layer 312 is larger than a doping concentration of the first structure layer 311 and is larger than a doping concentration of the third structure layer 313. The stress release region includes a first stress release region corresponding to the second structure layer 312 and a second stress release region corresponding to the third structure layer 313, that is, the first stress release region is in contact with a sidewall of the second structure layer 312, and the second stress release region is in contact with a sidewall of the third structure layer 313. A doping concentration of the first stress release region is larger than the doping concentration of the heavily doped region and is larger than a doping concentration of the second stress release region.

Due to the relatively high doping concentration of the second structure layer 312, lattice mismatch between the second structure layer 312 and the sidewall of the recess is also relatively serious. Correspondingly, the doping concentration of the first stress release region in contact with the second structure layer 312 is set larger, such that more vacancies or defects are caused in the first stress release region, thereby releasing stress caused by the formation of the second structure layer 312. Due to the relatively low doping concentrations of the first structure layer 311 and the third structure layer 313, lattice mismatch between them and the bottom wall and the sidewall of the recess is also relatively mild. Correspondingly, the doping concentrations of the heavily doped region in contact with the first structure layer 311 and the second stress release region in contact with the third structure layer 313 are set relatively small, such that reliability of the semiconductor structure can be prevented from being affected by the caused vacancies or defects while stress release (stress caused during the formation of the first structure layer 311 and stress caused during the formation of the third structure layer 313) is ensured.

Certainly, it can be understood that, the stress release region may alternatively be formed through doping after the first structure layer is formed. When there are multiple stress release regions, a step of forming each stress release region may alternatively be performed between steps of forming the structure layers. In an example, when the stress release regions include the first stress release region in contact with the second structure layer 312 and the second stress release region in contact with the third structure layer 313, the first stress release region may be formed through doping after the first structure layer 311 is formed, the second stress release region is formed through doping after the second structure layer 312 is formed, and then the third structure layer 313 is formed.

According to an exemplary embodiment of the present disclosure, a method of manufacturing a semiconductor structure is provided. The manufacturing method is used for manufacturing a transistor. In the manufacturing method, a gate oxide layer and a gate are formed on a base, and before a recess is formed, and ion implantation is performed on the base on two sides of each of the gate oxide layer and the gate to form a source and the gate. In another embodiment, ion implantation may alternatively be performed on a gradient layer after the gradient layer is formed, to form a source and the gate.

In the semiconductor structure and the manufacturing method thereof provided in the embodiments of the present disclosure, a recess is provided in a doped region of a base, and the recess is filled with a gradient layer, where a doping concentration of the gradient layer varies gradually from the bottom of the recess upwards. The gradient layer with the gradually varying doping concentration can better match a recess wall of the recess. In this way, electric leakage problems caused by lattice mismatch between the recess wall of the recess and the gradient layer can be reduced while carrier mobility is improved.

The embodiments or implementations of this specification are described in a progressive manner, and each embodiment focuses on differences from other embodiments. The same or similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more embodiments or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

In the semiconductor structure and the preparation method thereof provided in the embodiments of the present disclosure, a recess is provided in a doped region of a base, and the recess is filled with a gradient layer, where a doping concentration of the gradient layer varies gradually from the bottom of the recess upwards. The gradient layer with the gradually varying doping concentration can better match a recess wall of the recess. In this way, electric leakage problems caused by lattice mismatch between the recess wall of the recess and the gradient layer can be reduced while carrier mobility is improved.

1. A semiconductor structure, comprising:
a base, comprising a doped region;
a recess, located in the doped region; and
a gradient layer, filling the recess, wherein a doping concentration of the gradient layer varies gradually from a bottom of the recess upwards.

2. The semiconductor structure according to claim 1, wherein the gradient layer comprises multiple structure layers and a protective layer stacked in sequence, and doping concentrations of adjacent structure layers are different.

3. The semiconductor structure according to claim 2, wherein doping concentrations of the multiple structure layers first increase and then decrease from the bottom of the recess upwards.

4. The semiconductor structure according to claim 2, wherein the multiple structure layers are multiple silicon-germanium layers, and the protective layer is a silicon layer.

5. The semiconductor structure according to claim 2, wherein a thickness of each of the structure layers is 2 nm to 10 nm.

6. The semiconductor structure according to claim 2, further comprising: a conductive layer and a metal layer, wherein the protective layer comprises a through hole, the conductive layer fills the through hole, and the metal layer is provided on the conductive layer and electrically connected to the conductive layer.

7. The semiconductor structure according to claim 6, wherein a material of the conductive layer comprises cobalt silicide or nickel silicide; and
a material of the metal layer comprises tungsten, copper, gold, or aluminum.

8. The semiconductor structure according to claim 1, wherein the doped region comprises a heavily doped region and a lightly doped region, the heavily doped region and the lightly doped region are both located around the recess, and the heavily doped region is closer to the bottom of the recess.

9. A transistor, comprising the semiconductor structure according to claim 1, wherein the semiconductor structures are located in a source region and a drain region of the transistor.

10. A method of manufacturing a semiconductor structure, comprising:
providing a base, wherein the base comprises a doped region;
forming a recess in the doped region of the base; and
forming a gradient layer, wherein the gradient layer fills the recess, and a doping concentration of the gradient layer varies gradually from a bottom of the recess upwards.

11. The method of manufacturing according to claim 10, wherein the forming a gradient layer comprises:
forming a laminated structure in the recess, wherein the laminated structure comprises multiple structure layers stacked, and doping concentrations of adjacent structure layers are different; and
forming a protective layer, wherein the protective layer covers the laminated structure, and fills the recess.

12. The method of manufacturing according to claim 11, wherein doping concentrations of the multiple structure layers first increase and then decrease from the bottom of the recess upwards.

13. The method of manufacturing according to claim 11, wherein the forming a laminated structure in the recess comprises:
performing multiple rounds of an epitaxial growth in the recess, wherein each of the rounds of the epitaxial growth forms one of the structure layers.

14. The method of manufacturing according to claim 11, wherein the multiple structure layers are multiple silicon-germanium layers.

15. The method of manufacturing according to claim 14, wherein a germanium content difference between adjacent silicon-germanium layers is 1 wt% to 5 wt%.

16. The method of manufacturing according to claim 14, wherein among the multiple silicon-germanium layers, a germanium content of a silicon-germanium layer close to the bottom of the recess is 25 wt% to 30 wt%, a germanium content of a silicon-germanium layer with a largest germanium content is 35 wt% to 40 wt%, and a germanium content of a silicon-germanium layer close to a top of the recess is 25 wt% to 30 wt%.

17. The method of manufacturing according to claim 11, after the forming a gradient layer, the method of manufacturing a semiconductor structure further comprises:
removing a part of a structure of the protective layer, to form a through hole, wherein the through hole exposes a part of a top surface of the laminated structure;
filling the through hole with a metallic material, and forming a conductive layer by combining the metallic material with a material of the protective layer by using a high temperature annealing process; and
forming a metal layer on the conductive layer.

18. The method of manufacturing according to claim 10, before the forming a gradient layer, the method of manufacturing a semiconductor structure further comprises:
doping a second region located close to the bottom of the recess by using heavy ions and forming a heavily doped region.

19. The method of manufacturing according to claim 18, wherein the heavy ions comprise at least one of germanium, carbon, or helium.

20. The method of manufacturing according to claim 18, before forming the recess in the base, the method of manufacturing a semiconductor structure further comprises:
doping a first region located in a surface layer of the base and forming a lightly doped region, wherein the heavily doped region is located below the lightly doped region.
